(19) United States
(12) Patent Application Publication
(10) Pub. No.: US 2026/0239954 A1
(43) Pub. Date: Aug. 13, 2026

(54) SEMICONDUCTOR DEVICE AND METHOD FOR FORMING THE SAME

(71) Applicant: TAIWAN SEMICONDUCTOR MANUFACTURING COMPANY, LTD., Hsinchu (TW)

(72) Inventors: Po-Chin CHANG, Taichung City (TW); Kuan-Kan HU, Hsinchu (TW); Chia-Hung CHU, Taipei City (TW); Meng-Hsi CHUANG, Hsinchu City (TW); Yuting CHENG, Taoyuan City (TW); Sung-Li WANG, Hsinchu County (TW); Pinyen LIN, Rochester, NY (US)

(73) Assignee: TAIWAN SEMICONDUCTOR MANUFACTURING COMPANY, LTD., Hsinchu (TW)

(21) Appl. No.: 19/047,964

(22) Filed: Feb. 7, 2025

(51) Int. Cl. H01L 23/528; H01L 21/768; H01L 23/522; H01L 23/532; H10D 30/00; H10D 30/01; H10D 62/10; H10D 62/13; H10D 64/23; H10D 84/01; H10D 84/85

(52) U.S. Cl. CPC H10W 20/435; H10D 30/0191; H10D 30/502; H10D 62/121; H10D 62/151; H10D 64/254; H10D 64/256; H10D 84/017; H10D 84/0186; H10D 84/851; H10W 20/035; H10W 20/077; H10W 20/42; H10W 20/425; H10W 20/48

(57) ABSTRACT

A semiconductor device includes a substrate. A transistor is over the substrate. An interconnect structure is over and electrically connected to the plurality of transistor. The interconnect structure includes a via structure, an etch stop layer over the via structure, a dielectric layer over the etch stop layer, a metal line in the dielectric layer, wherein the metal line includes a barrier layer and a fill metal spaced apart from the dielectric layer by the barrier layer, wherein an electrical conductivity of the barrier layer is less than an electrical conductivity of the fill metal, a first nitride layer vertically between the via structure and the metal line, and second nitride layers on opposite sidewalls of the metal line and in contact with the dielectric layer.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. However, since feature sizes continue to decrease, fabrication processes continue to become more difficult to perform. Therefore, it is a challenge to form reliable semiconductor devices at smaller and smaller sizes.

As the semiconductor industry further progresses into technology process nodes in pursuit of higher device density, higher performance, and lower costs, challenges from both fabrication and design issues have led to stacked device structure configurations, such as complementary field effect transistors (C-FET) where an n-type multi-gate transistor and a p-type multi-gate transistor are stacked vertically, one over the other. While existing C-FET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view of a semiconductor device in accordance with some embodiments of the present disclosure.

FIGS. 2A to 14B illustrate a method in various stages of forming a semiconductor device in accordance with some embodiments of the present disclosure.

FIG. 15 is an enlarged view of a semiconductor device in accordance with some embodiments of the present disclosure.

FIGS. 16A to 17B illustrate a method in various stages of forming a semiconductor device in accordance with some embodiments of the present disclosure.

FIG. 18 is an enlarged view of a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

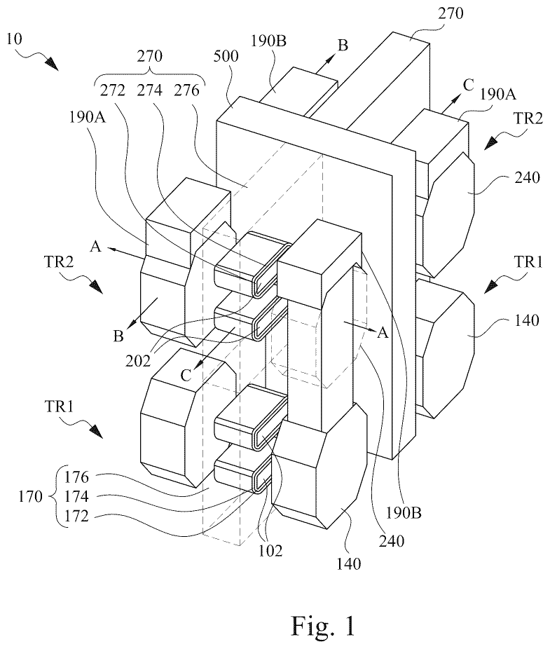

FIG. 1 is a perspective view of a semiconductor device in accordance with some embodiments of the present disclosure. In the present disclosure, a complementary FET (CFET) 10 is provided, and its manufacturing method will be disclosed in the following discussion. In a CFET 10, first transistors TR1 are disposed over a substrate (not shown), and second transistors TR2 are disposed vertically above the respective first transistors TR1. In some embodiments, the first transistors TR1 and the second transistors TR2 each may be field effect transistor (FET) and may both include gate-all-around (GAA) configuration, and thus the first transistors TR1 and the second transistors TR2 can also be referred to as GAA FETs. Each of the first transistors TR1 includes first semiconductor channel layers 102 vertically stacked one above another, a first metal gate structure 170 wrapping around each of the first semiconductor channel layers 102, and first source/drain epitaxy structures 140 on opposite ends of each of the first semiconductor channel layers 102. Similarly, each of the second transistors TR2 includes second semiconductor channel layers 202 vertically stacked one above another, a second metal gate structure 270 wrapping around each of the second semiconductor channel layers 202, and second source/drain epitaxy structures 240 on opposite ends of each of the second semiconductor channel layers 202. The first metal gate structure 170 may include an interfacial layer 172, a gate dielectric layer 174, and a gate electrode 176. Similarly, the second metal gate structure 270 may include an interfacial layer 272, a gate dielectric layer 274, and a gate electrode 276. In some embodiments, each of the first transistors TR1 has a first conductivity type (e.g., p-type) and each of the second transistors TR2 has a second conductivity type (e.g., n-type) different from the first conductivity type. In some embodiments, the first transistors TR1 can be referred to as P-FETs, and the second transistors TR2 can be referred to as N-FETs.

A dielectric structure 500 is disposed between two adjacent first transistors TR1, so as to electrically isolate the two adjacent first transistors TR1. Similarly, the dielectric structure 500 is disposed between two adjacent second transistors TR2, so as to electrically isolate the two adjacent second transistors TR2.

The CFET 10 further includes source/drain contacts 190A and 190B. The source/drain contacts 190A and 190B are disposed over the respective second source/drain epitaxy structures 240. In some embodiments, the source/drain contact 190A is in contact with top surface of the corresponding second source/drain epitaxy structure 240. On the other hand, the source/drain contact 190B may penetrate through the second source/drain epitaxy structure 240, and extends downwardly to top surface of the corresponding first source/drain epitaxy structure 140. As a result, the source/drain contact 190B electrically connects the second source/drain epitaxy structure 240 and the underlying first source/drain epitaxy structure 140.

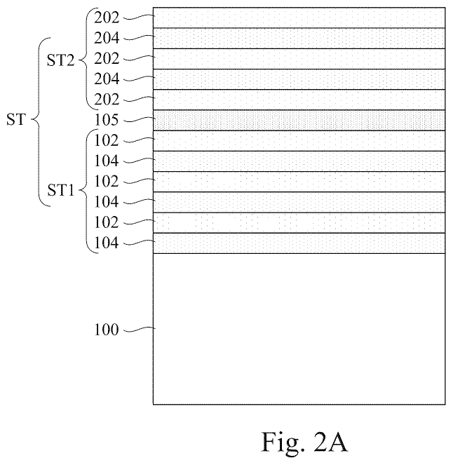

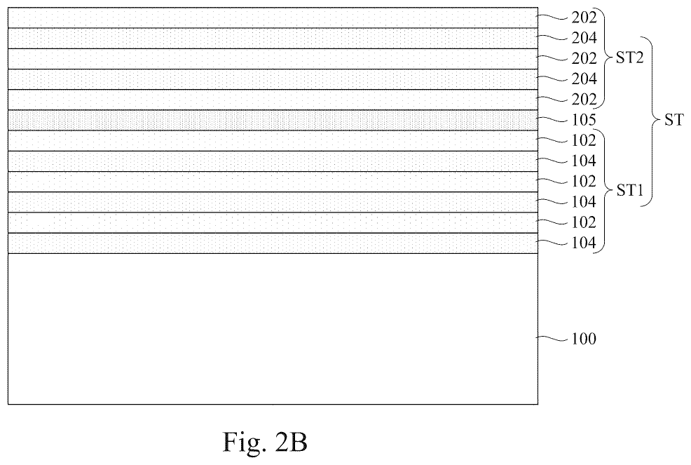

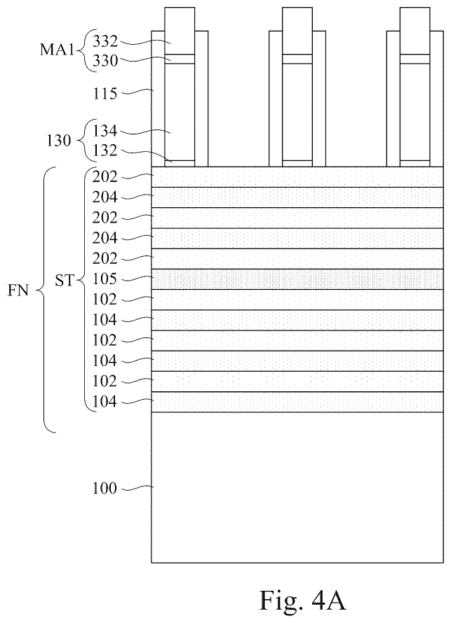

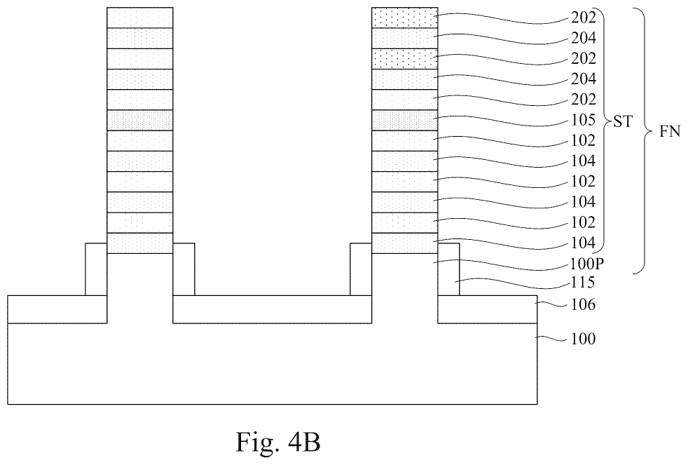

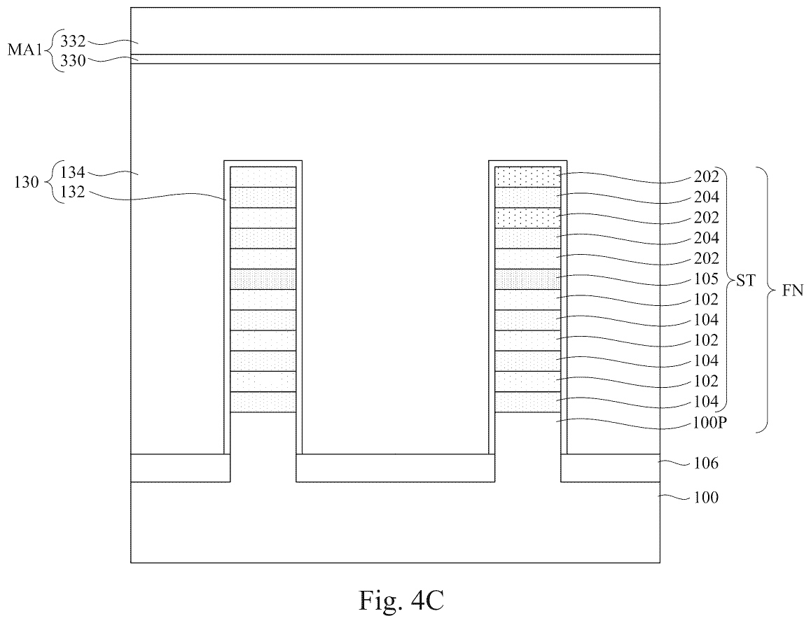

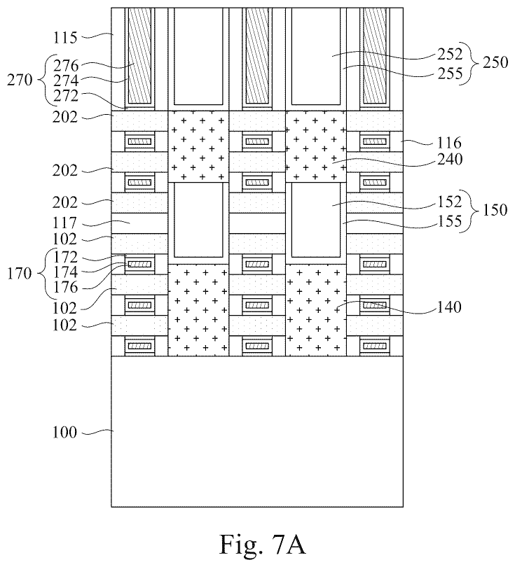

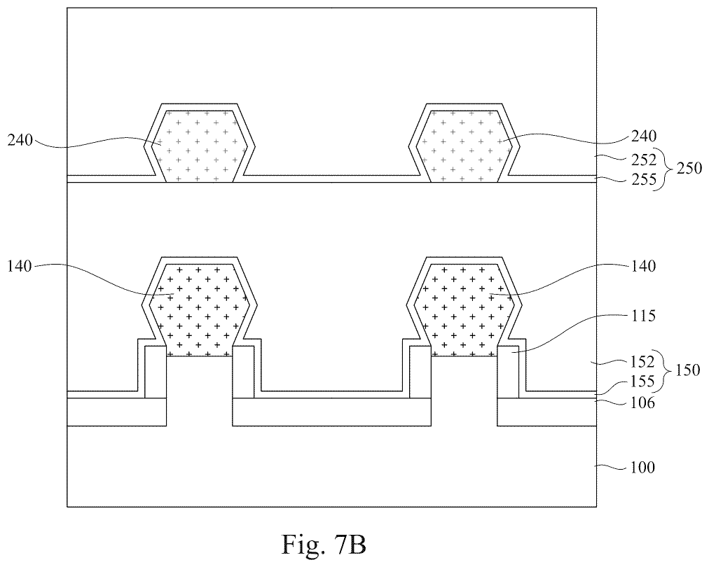

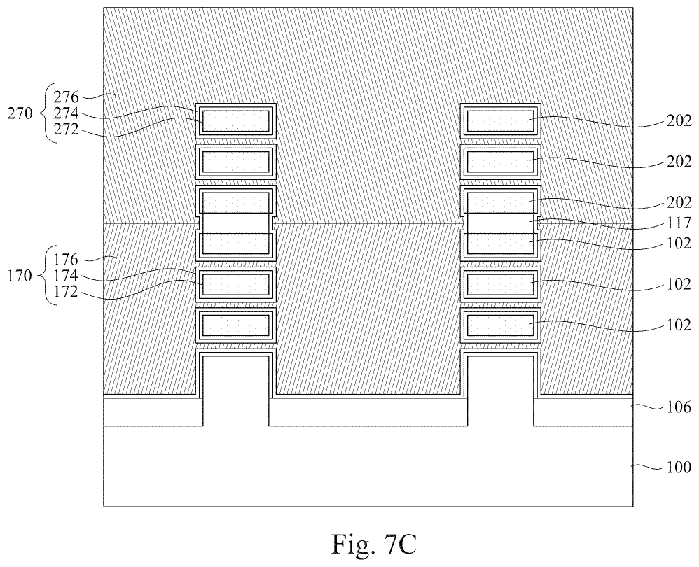

FIGS. 2A to 14B illustrate a method in various stages of forming a semiconductor device in accordance with some embodiments of the present disclosure. It is noted that FIGS. 2A, 3A, 4A, 5A, 6A, 7A, 8A, 9A, 10A, 11A, 12A, 13A, and 14A include cross-sectional views the same as the cross-sectional view along line A-A of FIG. 1. FIGS. 2B, 3B, 4B, 5B, 6B, 7B, 8B, 9B, 10B, 11B, 12B, 13B, and 14B include cross-sectional views the same as the cross-sectional view along line B-B of FIG. 1. FIGS. 4C and 7C include cross-sectional views the same as the cross-sectional view along line C-C of FIG. 1. Although FIGS. 2A to 14B are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part. It is noted that some elements of FIGS. 2A to 14B may be similar to those described with respect to FIG. 1, and thus relevant details will not be repeated for brevity.

Reference is made to FIGS. 2A and 2B. Shown there is a substrate 100. Generally, the substrate 100 may include a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally include the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), oxide semiconductors (e.g., ZnO, SnO₂, TiO₂, Ga₂O₃, and the like) or combinations thereof. The semiconductor materials may be doped or undoped. Other substrates that may be used include multi-layered substrates, gradient substrates, or hybrid orientation substrates.

A semiconductor stack ST is formed over the substrate 100. The semiconductor stack ST includes a first stack ST1 of alternating semiconductor layers 102 and 104, a semiconductor layer 105 disposed over the first stack ST1, and a second stack ST2 of alternating semiconductor layers 202 and 204 over the semiconductor layer 105. In some embodiments, the semiconductor layers 102 and 202 may be made of pure silicon layers that are free of germanium. The semiconductor layers 102 and 202 may also be substantially pure silicon layers, for example, with a germanium percentage lower than about 1 percent. The semiconductor layers 104, 105, and 204 may be made of silicon germanium, while the semiconductor layer 105 may include a higher germanium composition than the semiconductor layers 104 and 204. For example, the germanium percentage (atomic percentage concentration) of the semiconductor layer 105 is in a range from about 60 percent and about 80 percent, and the germanium percentage (atomic percentage concentration) of the semiconductor layers 104 and 204 is in a range from about 20 percent and about 40 percent. In some embodiments, the semiconductor layers 102, 104, 105, 202, and 204 may be deposited using suitable deposition process, such as selective epitaxial growth (SEG), chemical vapor deposition (CVD), molecular beam epitaxy (MBE), or other suitable process(es). In some embodiments, the semiconductor layers 104 and 204 may be removed during a replacement gate (RPG) process, and thus the semiconductor layers 104 and 204 can also be referred to as sacrificial layers.

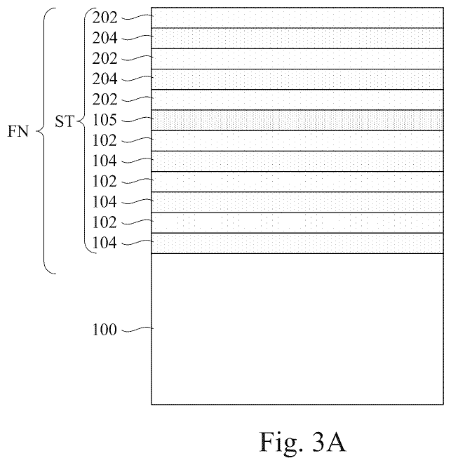

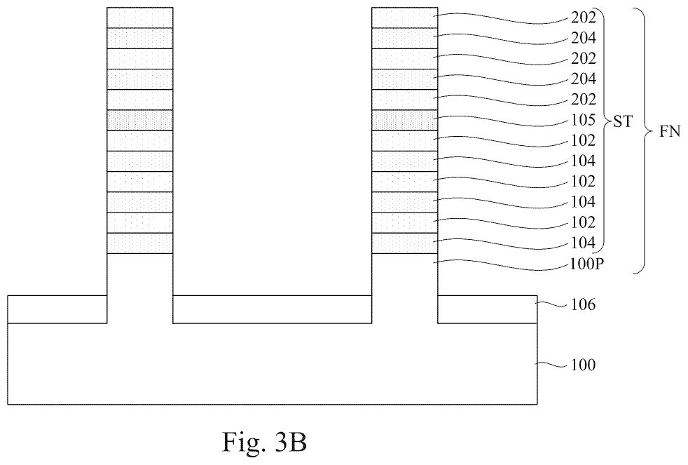

Reference is made to FIGS. 3A and 3B. A patterning process is performed to the semiconductor stack ST and the substrate 100 to form fin structures FN. In some embodiments, the patterning process may include forming a patterned photoresist layer over the stack ST, and then performing an etching process to remove unwanted portions of the semiconductor stack ST and the substrate 100 exposed by the patterned photoresist layer. Each of the fin structures FN may include a remaining portion of the semiconductor stack ST and a semiconductor strip 100P protruding over the substrate 100. In some embodiments, the etching process may include wet etch, dry etch, or the like.

After the fin structures FN are formed, isolation structures 106 are formed over the substrate 100 and laterally surrounding the fin structures FN. In some embodiments, the isolation structures 106 may be in contact with sidewalls of the semiconductor strip 100P of the substrate 100. The isolation structures 106 may be shallow trench isolation (STI) structures, suitable isolation structures, combinations of the foregoing, or the like. In some embodiments, the isolation structures 106 may be made of oxide (e.g., silicon oxide), nitride (e.g., silicon nitride), or combinations thereof. In some embodiments, the isolation structures 106 may include a dielectric constant that is in a range from about 3 to about 5.

Reference is made to FIGS. 4A, 4B, and 4C. Dummy gate structures 130 are formed over the substrate 100 and crossing the fin structures FN (see FIG. 4C). In some embodiments, each of the dummy gate structures 130 includes a dummy gate dielectric 132 and a dummy gate electrode 134 over the dummy gate dielectric 132. The dummy gate dielectric 132 may be, for example, silicon oxide, silicon nitride, a combination thereof, or the like, and may be deposited or thermally grown according to acceptable techniques. The dummy gate electrode 134 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals.

The dummy gate electrode 134 and the dummy gate dielectric 132 may be formed by, for example, depositing a dummy dielectric layer and a dummy gate layer over the substrate 100, forming patterned masks MA1 over the dummy gate layer, and then performing an etching process to the dummy dielectric layer and the dummy gate layer by using the patterned masks MA1 as etch mask. In some embodiments, the dummy gate electrode 134 may be deposited by physical vapor deposition (PVD), chemical vapor deposition (CVD), sputter deposition, or other techniques for depositing the selected material. In some embodiments, the dummy gate dielectric 132 may be formed by thermal oxidation.

In some embodiments, each of the patterned masks MA1 includes a first hard mask 330 and a second hard mask 332 over the first hard mask 330. The first hard mask 330 and the second hard mask 332 may be made of different materials. In some embodiments, the first hard mask 330 may be formed of silicon nitride, and the second hard mask 332 may be formed of silicon oxide.

Spacers 115 are formed on opposite sidewalls of each of the dummy gate structures 130 (see FIG. 4A), and on opposite sidewalls of the fin structures FN (see FIG. 4B). In some embodiments, portions of the spacers 115 on opposite sidewalls of each of the dummy gate structures 130 can be referred to as gate spacers, and portions of the spacers 115 on opposite sidewalls of the fin structures FN can be referred to as fin spacers. In some embodiments, the spacers 115 may be formed of silicon oxide, silicon nitride, silicon oxynitride, combinations thereof. In some embodiments, the spacers 115 may be formed by, for example, depositing a spacer layer blanket over the substrate, and then performing an anisotropic etching process to remove horizontal portions of the spacer layer, such that vertical portions of the spacer layer remain on sidewalls of the dummy gate structures 130 and on sidewalls of the fin structures FN. In some embodiments, the remaining vertical portions of the spacer layer can be referred to as the spacers 115. The spacer layer may be deposited using techniques such CVD, ALD, or the like.

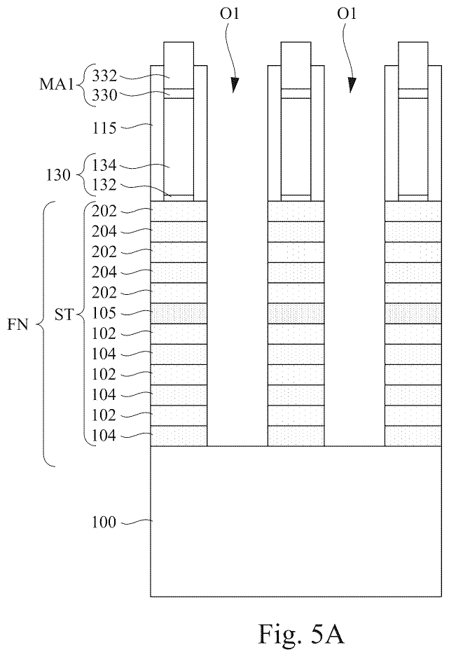

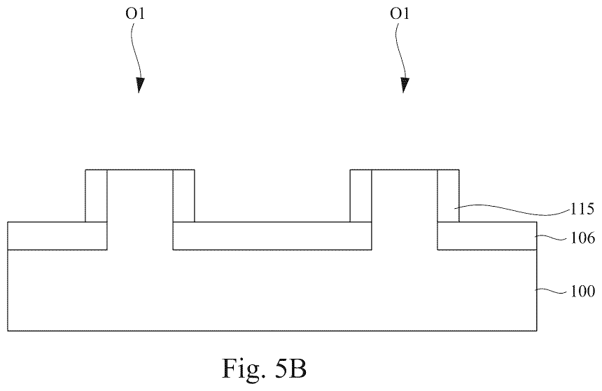

Reference is made to FIGS. 5A and 5B. An etching process is performed to remove portions of the fin structures FN (or the stacks ST) by using the dummy gate structures 130 and the spacers 115 as etch mask, so as to form source/drain openings O1 in the fin structures FN (or in the stacks ST). In some embodiments, the etching process may be wet etch, dry etch, or combinations thereof. In some embodiments, the bottommost ends of the source/drain openings O1 may be lower than the bottommost semiconductor layer 104.

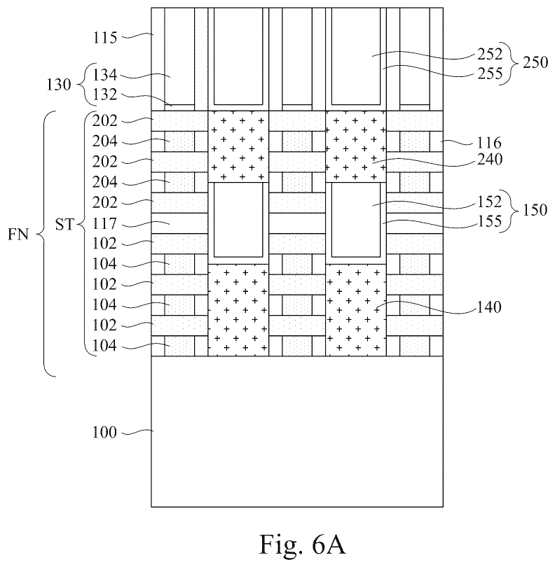

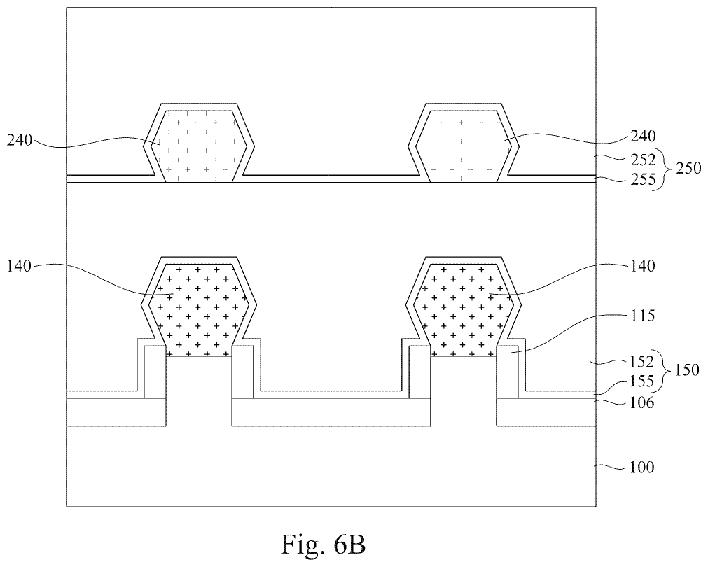

Reference is made to FIGS. 6A and 6B. Inner spacers 116 and dielectric isolation layers 117 are formed. Forming inner spacers 116 and dielectric isolation layers 117 may include an etching process that laterally etches the semiconductor layers 104 and 204 and removes the semiconductor layers 105. The etching process may be isotropic and may be selective to the material of the semiconductor layers 104, 105, and 204, so that the semiconductor layers 104, 105, and 204 are etched at a faster rate than the semiconductor layers 102 and 202. The etching process may also be selective to the material of the semiconductor layers 105, so that the semiconductor layers 105 are etched at a faster rate than the semiconductor layers 104 and 204. In this manner, the semiconductor layers 105 may be completely removed, while the semiconductor layers 104 and 204 are laterally shortened. In some embodiments where the semiconductor layers 105 are formed of germanium or silicon germanium with a higher germanium atomic percentage than the semiconductor layers 104 and 204, the semiconductor layers 104 and 204 are formed of silicon germanium with a lower germanium atomic percentage than the semiconductor layers 105, and the semiconductor layers 102 and 104 are formed of silicon free from germanium, the etch process may comprise a dry etch process using chlorine-containing gas, with or without a plasma.

Inner spacers 116 are formed on sidewalls of the recessed semiconductor layers 104 and 204, and dielectric isolation layers 117 are formed between the topmost semiconductor layer 102 and the bottommost semiconductor layer 104. As subsequently described in greater detail, source/drain structures will be subsequently formed in the source/drain openings O1, and the semiconductor layers 104 and 204 will be replaced with corresponding gate structures. The inner spacers 116 act as isolation features between the subsequently formed source/drain structures and the subsequently formed gate structures. Further, the inner spacers 116 may be used to prevent damage to the subsequently formed source/drain structures by subsequent etch processes, such as the etch processes used to form gate structures. Dielectric isolation layers 117, on the other hand, are used to isolate the upper semiconductor layers 104 from the lower semiconductor layers 102.

The inner spacers 116 and the dielectric isolation layers 117 may be formed by conformally depositing an insulating material in the source/drain openings O1, on sidewalls of the semiconductor layers 104 and 204, and in the gap between the topmost semiconductor layer 102 and the bottommost semiconductor layer 104, and then etching the insulating material. The insulating material may be a non-low-k dielectric material, which may be a carbon-containing dielectric material such as silicon oxycarbonitride, silicon oxycarbide, or the like. The insulating material may be formed by a deposition process, such as ALD, CVD, or the like. The etching of the insulating material may be anisotropic or isotropic. The insulating material, when etched, has portions remaining in the sidewalls of the semiconductor layers 104 and 204 (thus forming the inner spacers 116) and has portions remaining in the gap between the topmost semiconductor layer 102 and the bottommost semiconductor layer 104 (thus forming the dielectric isolation layers 117). As a result, the inner spacers 116 and the dielectric isolation layers 117 may be made of the same dielectric material.

First source/drain epitaxy structures 140 are formed in the openings O1, respectively. The first source/drain epitaxy structures 140 may be formed by suitable deposition process, such as a selective epitaxial growth (SEG) process. In some embodiments, the SEG process may selectively grow a semiconductor material on exposed semiconductor surfaces, such as the exposed surfaces of the substrate 100 and the exposed surfaces of the semiconductor layers 102. In some embodiments, an implantation process may be performed to the first source/drain epitaxy structures 140. For example, the implantation process may include p-type dopants, such as boron (B), gallium (Ga), indium (In), aluminum (Al), or the like, such that the first source/drain epitaxy structures 140 are p-type epitaxy structures. In some embodiments where the first source/drain epitaxy structures 140 are p-type epitaxy structures, the first source/drain epitaxy structures 140 may be made of silicon germanium (SiGe) or silicon (Si).

A contact etch stop layer (CESL) 155 is formed covering the first source/drain epitaxy structures 140. Afterwards, an interlayer dielectric (ILD) layer 152 is formed over the CESL 155. Then, an etching back process is performed to lower top surfaces of the CESL 155 and the ILD layer 152, such that sidewalls of the semiconductor layers 202 are exposed through the source/drain openings O1. In some embodiments, the CESL 155 and the ILD layer 152 can be collectively referred to as an isolation structure 150. In some embodiments, the topmost semiconductor layer 102 and the bottommost semiconductor layer 202 are in contact with the CESL 155 of the isolation structure 150.

In some embodiments, the CESL 155 may be nitride (such as silicon nitride), and the ILD layer 152 may be oxide (such as silicon oxide). In some embodiments, the CESL 155 may be a dielectric layer including silicon nitride, silicon oxynitride or other suitable materials. In some embodiments, the ILD layer 152 may include silicon oxide, silicon nitride, silicon oxynitride, tetraethoxysilane (TEOS), phosphosilicate glass (PSG), borophosphosilicate glass (BPSG), low-k dielectric material, and/or other suitable dielectric materials. Examples of low-k dielectric materials include, but are not limited to, fluorinated silica glass (FSG), carbon doped silicon oxide, amorphous fluorinated carbon, parylene, bis-benzocyclobutenes (BCB), or polyimide. In some embodiments, the ILD layer 152 may include a dielectric constant that is in a range from about 3 to about 5. In some embodiments, the material of the CESL 155 may include a higher dielectric constant than the material of the ILD layer 152. The CESL 155 and the ILD layer 152 can be formed using, for example, CVD, ALD or other suitable techniques.

Second source/drain epitaxy structures 240 are formed on opposite ends of each of the semiconductor layers 202. In some embodiments, the second source/drain epitaxy structures 240 may be formed by a selective epitaxial growth (SEG) process. The SEG process may selectively grow a semiconductor material on exposed semiconductor surfaces, such as the exposed surfaces of the semiconductor layers 202. In some embodiments, an implantation process may be performed to the second source/drain epitaxy structures 240. For example, the implantation process may include n-type dopants, such as phosphorus (P), arsenic (As), or antimony (Sb), or the like, such that the second source/drain epitaxy structures 240 are n-type epitaxy structures. In some embodiments where the second source/drain epitaxy structures 240 are n-type epitaxy structures, the second source/drain epitaxy structures 240 may be made of silicon (Si).

A contact etch stop layer (CESL) 255 is formed covering the second source/drain epitaxy structures 240. Afterwards, an interlayer dielectric (ILD) layer 252 is formed over the CESL 255. Then, a planarization process, such as CMP, is performed to remove excess materials of the CESL 255 and the ILD layer 252 until the dummy gate structures 130 are exposed. In some embodiments, the patterned masks MA1 are removed during the planarization process. In some embodiments, the CESL 255 and the ILD layer 252 can be collectively referred to as an isolation structure 250. The materials of the CESL 255 and the ILD layer 252 may be similar to the materials of the CESL 155 and the ILD layer 152, respectively. For example, the CESL 255 may be nitride (such as silicon nitride), and the ILD layer 252 may be oxide (such as silicon oxide).

Reference is made to FIGS. 7A, 7B, and 7C. The dummy gate structures 130 are removed to form gate trenches between each pair of the gate spacers 115. Then, an etching process is performed to remove the semiconductor layers 104 and 204 through the gate trenches, such that the semiconductor layers 102 and 202 are suspended over the substrate 100 (see FIG. 7C).

Interfacial layers 172 and 272 are formed on exposed surfaces of the semiconductor layers 102 and 202, respectively. Then, gate dielectric layers 174 and 274 are formed over the interfacial layers 172 and 272, respectively. In some embodiments, the interfacial layers 172 and 272 may be formed using a same deposition process, and the gate dielectric layers 174 and 274 may be formed using a same deposition process.

After the interfacial layers 172 and 272 and the gate dielectric layers 174 and 274 are formed, gate electrodes 176 are formed in the gate trenches and over the gate dielectric layers 174. The gate electrodes 176 are then etched back, such that the remaining gate electrodes 176 are at the lower portion of the gate trenches. Accordingly, first metal gate structures 170 are formed. In greater detail, the first metal gate structures 170 are formed in bottom portions of the gate trenches, such that the first metal gate structures 170 may wrap around the respective semiconductor layers 102. In some embodiments, each of the first metal gate structures 170 may include the interfacial layer 172, the gate dielectric layer 174 over the interfacial layer 172, and the gate electrode 176 over the gate dielectric layer 174.

In some embodiments, the interfacial layers 172 and 272 may be made of oxide, such as aluminum oxide (Al₂O₃), silicon oxide (SiO₂), or the like. In some embodiments, the gate dielectric layers 174 and 274 may include high-k dielectric. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof.

The gate electrodes 176 may include work function metal layer(s) and a filling metal. The work function metal layer may be an n-type or p-type work function layer. Exemplary p-type work function metals include TiN, TaN, Ru, Mo, Al, WN, ZrSi₂, MoSi₂, TR1 asi₂, NiSi₂, WN, other suitable p-type work function materials, or combinations thereof. Exemplary n-type work function metals include Ti, Ag, TaAl, TaAlC, TiAlN, TaC, TaCN, TR1 asiN, Mn, Zr, other suitable n-type work function materials, or combinations thereof. The work function layer may include a plurality of layers. The filling metal may include tungsten (W), aluminum (Al), copper (Cu), or another suitable conductive material(s).

Gate electrodes 276 are formed in the gate trenches and over the first metal gate structures 170. Accordingly, second metal gate structures 270 are formed. In greater detail, the second metal gate structures 270 are formed in upper portions of the gate trenches and above the first metal gate structures 170, such that the second metal gate structures 270 may wrap around the respective semiconductor layers 202. In some embodiments, each of the second metal gate structures 270 may include the interfacial layer 272, the gate dielectric layer 274 over the interfacial layer 272, and the gate electrode 276 over the gate dielectric layer 274. The materials of the gate electrode 276 may be similar to those described with respect to the gate electrode 176, and thus relevant details will not be repeated for brevity.

The first metal gate structure 170, the first source/drain epitaxy structures 140 on opposite sides of the first metal gate structure 170, and the semiconductor layers 102 that are in contact with the first source/drain epitaxy structures 140 may collectively serve as the first transistor TR1 as described in FIG. 1. In such condition, the semiconductor layers 102 that are in contact with the first source/drain epitaxy structures 140 may also be referred to as channel layers of the first transistor TR1. Similarly, the second metal gate structure 270, the second source/drain epitaxy structures 240 on opposite sides of the second metal gate structure 270, and the semiconductor layers 202 that are in contact with the second source/drain epitaxy structures 240 may collectively serve as the second transistor TR2 as described in FIG. 1. In such condition, the semiconductor layers 202 that are in contact with the second source/drain epitaxy structures 240 may also be referred to as channel layers of the second transistor TR2. In FIG. 7A, opposite ends of the topmost semiconductor layer 102 are in contact with the isolation structures 150, and are not in contact with the first source/drain epitaxy structures 140. Thus, the topmost semiconductor layer 102 may not function as a channel layer of the first transistor TR1. Similarly, opposite ends of the bottommost semiconductor layer 202 are in contact with the isolation structure 150, and are not in contact with the second source/drain epitaxy structures 240. Thus, the topmost bottommost semiconductor layer 202 may not function as a channel layer of the second transistor TR2.

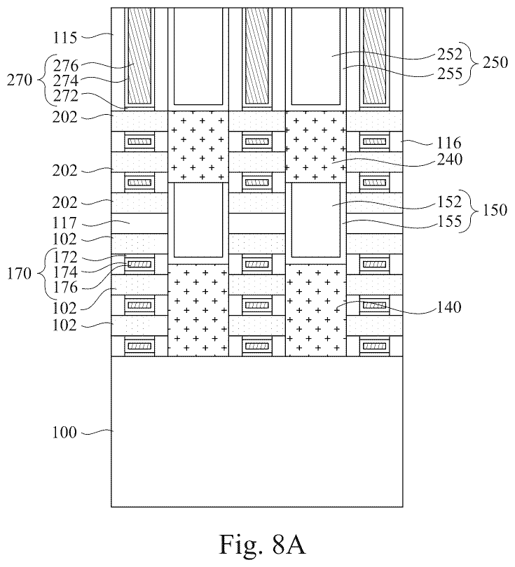

Reference is made to FIGS. 8A and 8B. A dielectric structure 500 is formed. As shown in FIG. 8B, the dielectric structure 500 may cut through the isolation structures 150 and 250. In some embodiments, the dielectric structure 500 may extend through the isolation structures 106 and in contact with the substrate 100. In some embodiments, the dielectric structure 500 may also be referred to as a cut-metal-gate (CMG) isolation structure.

The dielectric structure 500 may be made of nitride (e.g., silicon nitride), oxide (e.g., silicon oxide), combinations thereof, or suitable dielectric material. The dielectric structure 500 may be formed by, for example, etching the first metal gate structure 170, the second metal gate structure 270, and the isolation structures 150 and 250 to form an opening, depositing a dielectric material in the opening, and then performing a planarization process (such as CMP) to remove excess materials of the dielectric material.

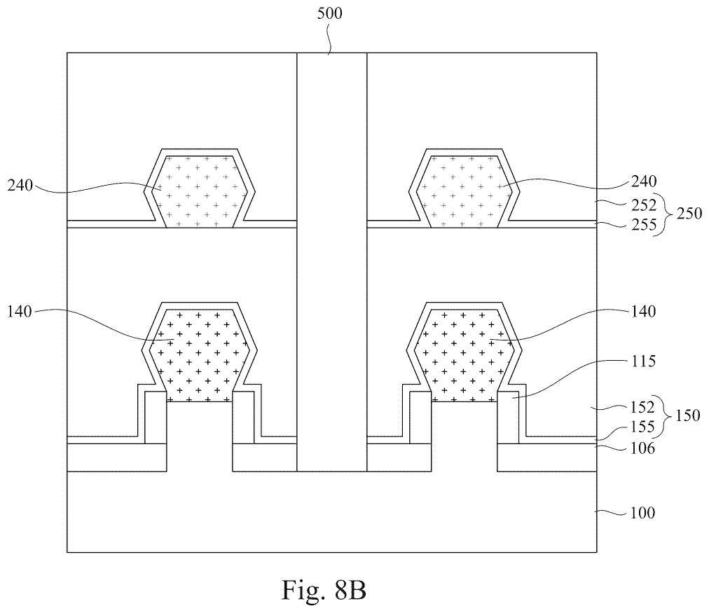

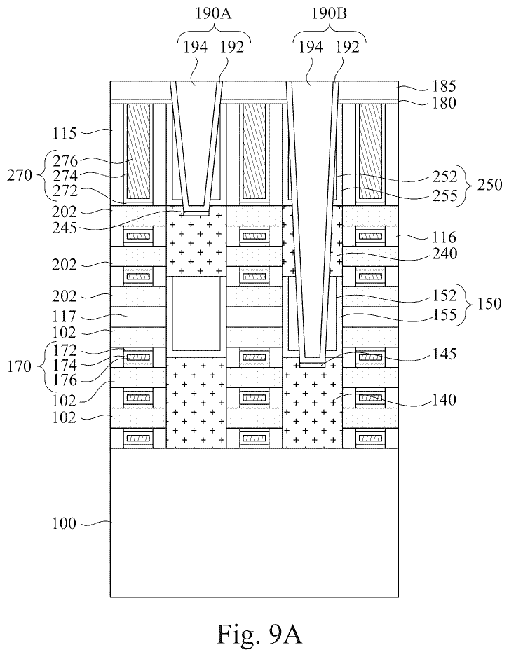

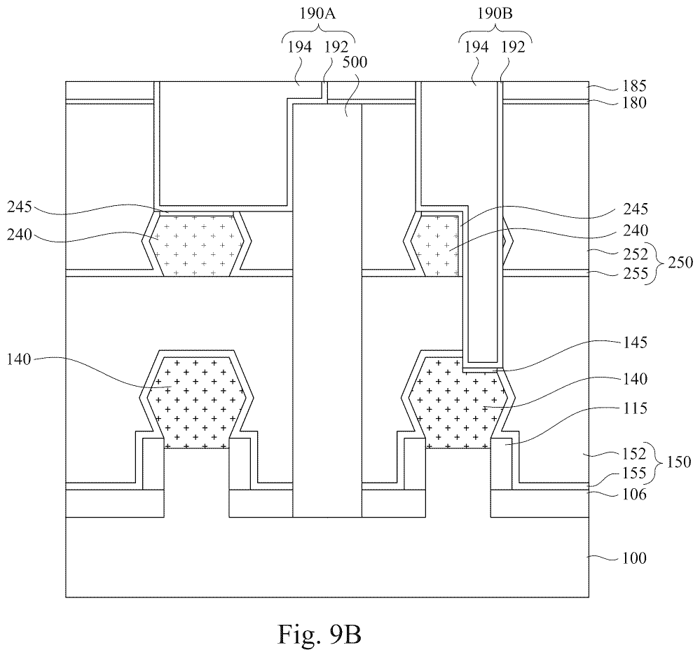

Reference is made to FIGS. 9A and 9B. An etch stop layer (ESL) 180 is formed over the isolation structures 250 and the second metal gate structures 270. Afterwards, an interlayer dielectric (ILD) layer 185 is formed over the ESL 180. The materials of the ESL 180 and the ILD layer 185 may be similar to the materials of the CESL 155 and the ILD layer 152, respectively. For example, the ESL 180 may be nitride, and the ILD layer 185 may be oxide. The ESL 180 and the ILD layer 185 can be formed using, for example, CVD, ALD or other suitable techniques.

Source/drain contacts 190A and 190B are formed. In greater detail, the source/drain contact 190A may be formed extending through the ILD layer 185, the ESL 180, and the isolation structure 250, and electrically connected to the respective second source/drain epitaxy structure 240. On the other hand, the source/drain contact 190B may be formed extending through the ILD layer 185, the ESL 180, the isolation structure 250, the respective second source/drain epitaxy structure 240, and the isolation structure 150, and electrically connected to the respective second source/drain epitaxy structure 240 and the respective first source/drain epitaxy structure 140.

In some embodiments, a first opening may be formed extending through the ILD layer 185, the ESL 180, and the isolation structure 250, to expose the respective second source/drain epitaxy structure 240. A second opening may be formed extending through the ILD layer 185, the ESL 180, the isolation structure 250, the respective second source/drain epitaxy structure 240, and the isolation structure 150, to expose the respective second source/drain epitaxy structure 240 and the respective first source/drain epitaxy structure 140. The source/drain contacts 190A and 190B may be formed in the first and second openings, respectively. In some embodiments, prior to forming the source/drain contacts 190A and 190B, silicide layers 145 and 245 may be formed on the exposed surfaces of the first source/drain epitaxy structures 140 and the second source/drain epitaxy structures 240, respectively. The silicide layers 145 and 245 may include titanium silicide (TiSi), while the disclosure is not limited thereto. In some embodiments, the materials of the silicide layers 145 and 245 may include a higher electrical conductivity than the materials of the source/drain structures 140 and 240.

The source/drain contacts 190A and 190B each may include a barrier layer 192 and a conductive plug 194 over the barrier layer 192, in which the barrier layer 192 may lines opposite sidewalls and bottom surface of the conductive plug 194. In some embodiments, the barrier layer 192 may include titanium nitride (TiN), tantalum nitride (TaN), or other suitable materials. In some embodiments, the conductive plug 194 may include tungsten (W), molybdenum (Mo), ruthenium (Ru), or other suitable materials. In some embodiments, the materials of the source/drain contacts 190A and 190B may include a higher electrical conductivity than the materials of the electrical conductivities of the source/drain structures 140 and 240.

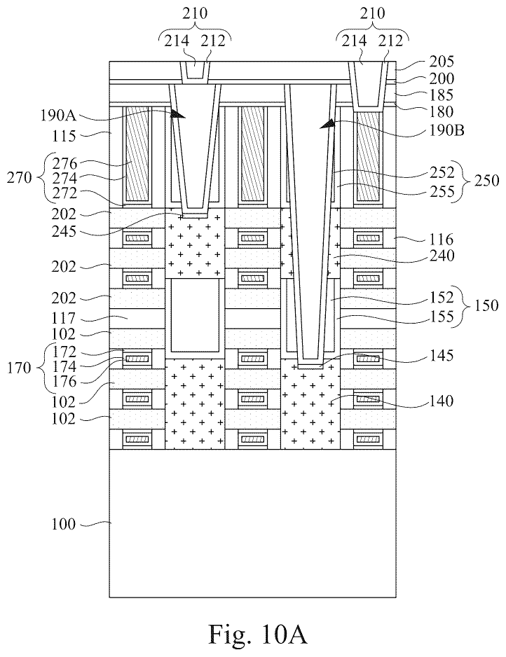

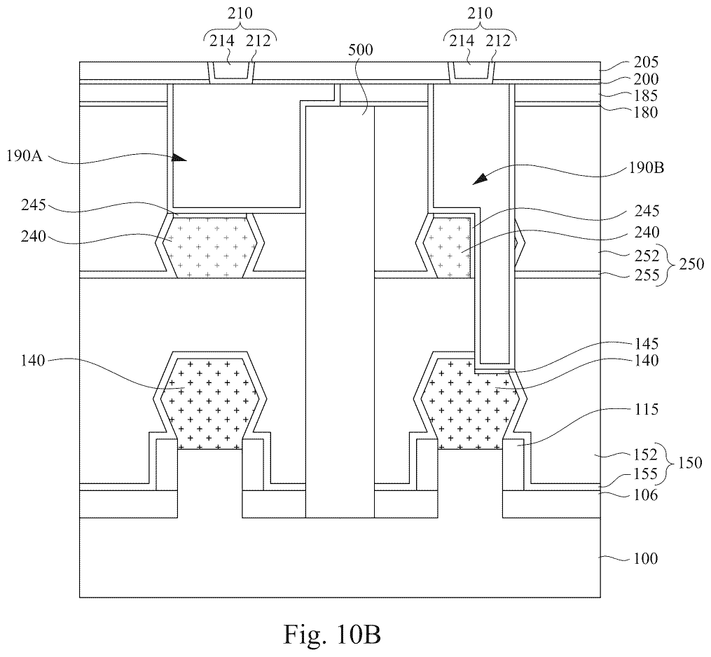

Reference is made to FIGS. 10A and 10B. An etch stop layer (ESL) 200 is formed over the ILD layer 185. Afterwards, an interlayer dielectric (ILD) layer 205 is formed over the ESL 200. The materials of the ESL 200 and the ILD layer 205 may be similar to the materials of the CESL 155 and the ILD layer 152, respectively. For example, the ESL 200 may be nitride, and the ILD layer 205 may be oxide. For example, the ESL 200 and the ILD layer 205 may be aluminum nitride and silicon oxide, respectively. The ESL 200 and the ILD layer 205 can be formed using, for example, CVD, ALD or other suitable techniques. In some embodiments, the ESL 200 and the ILD layer 205 can be collectively referred to as a dielectric structure.

Afterwards, via structures 210 are formed in contact with the source/drain contacts 190A and 190B, and the gate structures 270, respectively. In greater detail, the via structures 210 that are in contact with the source/drain contacts 190A and 190B may penetrate through the ILD layer 205 and the ESL 200, and may be referred to as source/drain via structures. On the other hand, the via structures 210 that are in contact with the gate structures 270 may penetrate through the ILD layer 205, the ESL 200, the ILD layer 185, and the ESL 180, and may be referred to as gate via structures. The via structures 210 may be formed by, for example, patterning the ILD layer 205, the ESL 200, the ILD layer 185, and the ESL 180 to form openings that expose the source/drain contacts 190A and 190B, and the gate structures 270, filling the openings with conductive materials, and then performing a planarization process (e.g., CMP) to remove excess conductive materials until the ILD layer 205 is exposed.

In some embodiments, each of the via structures 210 may include a via 214 and a barrier layer 212 lining sidewalls and bottom surface of the via 214. In some embodiments, the barrier layer 212 may include titanium nitride (TiN), tantalum nitride (TaN), or other suitable materials. In some embodiments, the via 214 may include tungsten (W), molybdenum (Mo), ruthenium (Ru), or other suitable materials. In some embodiments, the barrier layer 212 may be a metal nitride layer, and the via 214 is a pure metal layer.

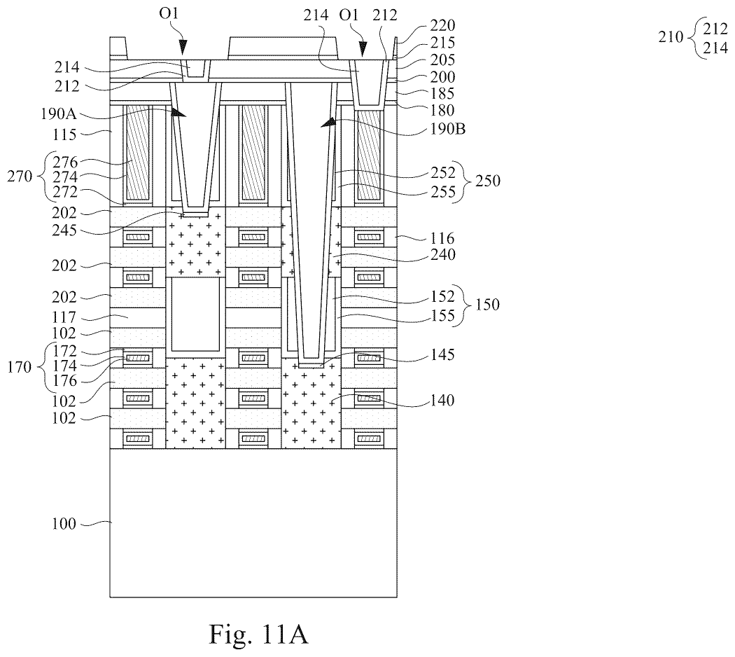

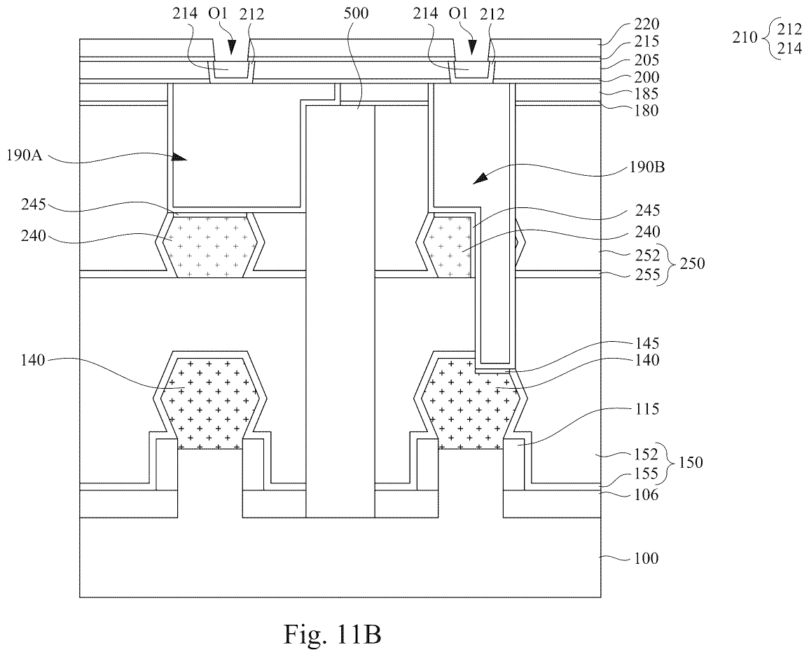

Reference is made to FIGS. 11A and 11B. An etch stop layer (ESL) 215 is formed over the ILD layer 205, and an interlayer dielectric (ILD) layer 220 is formed over the ESL 215. The materials of the ESL 215 and the ILD layer 220 may be similar to the materials of the CESL 155 and the ILD layer 152, respectively. For example, the ESL 215 may be nitride, and the ILD layer 220 may be oxide. For example, the ESL 215 and the ILD layer 220 may be aluminum nitride and silicon oxide, respectively. The ESL 215 and the ILD layer 220 can be formed using, for example, CVD, ALD or other suitable techniques. In some embodiments, the ESL 215 and the ILD layer 220 can be collectively referred to as a dielectric structure. In some embodiments, the dielectric constant of the materials of the ILD layer 152, 252, 205, and 220 may be lower than the dielectric constant of the materials of the gate dielectric layers 174 and 274.

The ILD layer 220 and the ESL 215 are patterned to form openings O1 that expose the via structures 210, respectively. In greater detail, each of the openings O1 expose at least the top surface of the via 214 of the corresponding via structures 210. In some embodiments, the openings O1 may also expose top surface of the ILD layer 205 (see FIG. 11A). The openings O1 may be formed using suitable photolithography process.

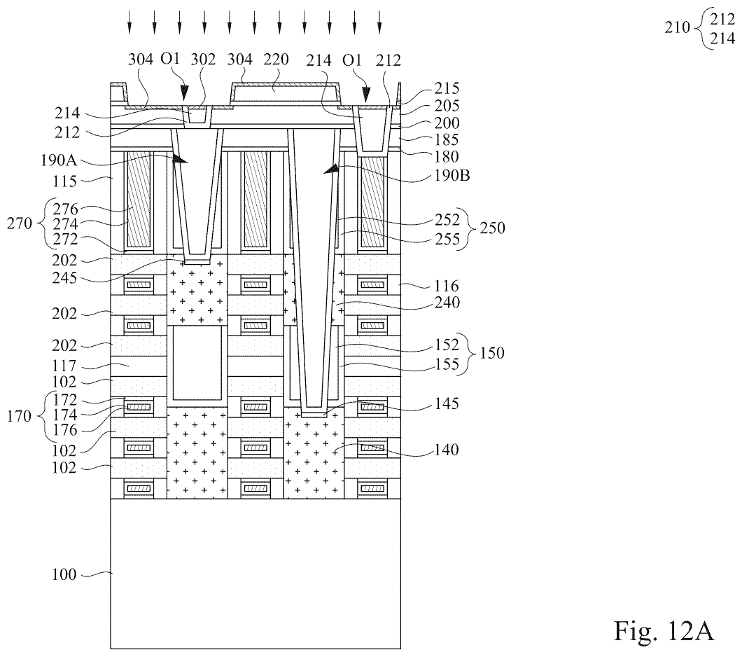

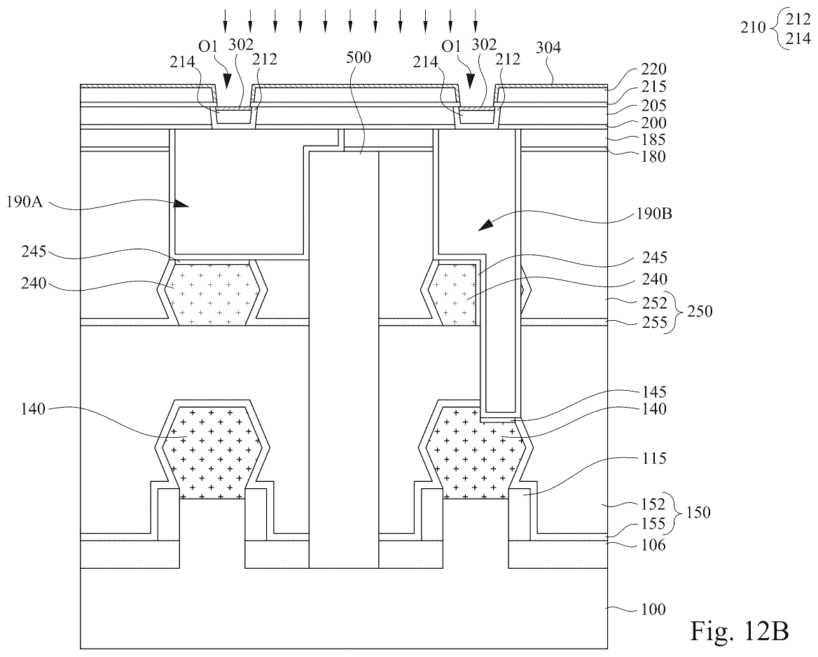

Reference is made to FIGS. 12A and 12B. A nitridation process is performed, so as to form nitride layers lining portions of the exposed surfaces of the structure of FIGS. 11A and 11B. In greater detail, nitride layers 302 are formed on the exposed surfaces of the vias 214 of the via structures 210, and nitride layers 304 are formed along the exposed surfaces of the ILD layers 220 and 205.

As mentioned above, because the via 214 of the via structures 210 may be a pure metal layer, such as tungsten (W), molybdenum (Mo), ruthenium (Ru), the nitride layers 302 may be a nitride of the material of the via 214. For example, the nitride layers 302 may be metal nitride, such as tungsten nitride (WN), molybdenum nitride (MoN), ruthenium nitride (RuN). However, because the barrier layer 212 of the via structures 210 may be a metal nitride layer (e.g., TiN, TaN, etc.), the nitridation process may not nitridize the barrier layer 212 of the via structures 210. That is, the nitridation process only nitridize the via 214 of the via structures 210. As a result, the nitride layer 302 over the via 214 may be spaced apart from the adjacent nitride layer 304 on the ILD layer 205 through a corresponding barrier layer 212.

On the other hand, with respect to the nitride layers 304, because the ILD layers 220 and 205 may be an oxide layer (e.g., silicon oxide), the nitride layers 304 may be a nitride of the material of the ILD layers 220 and 205. For example, the nitride layers 304 may be silicon oxynitride (SiON). However, because the ESL 215 may be a nitride layer (e.g., silicon nitride or aluminum nitride.), the nitridation process may not nitridize the ESL 215. That is, the nitridation process only nitridize the ILD layers 220 and 205. As a result, the nitride layer 304 over the ILD layer 215 may be spaced apart from the adjacent nitride layer 304 on the ILD layer 205 through a corresponding ESL 215. As discussed above, the nitride layers 302 and 304 are made of different nitrides. In some embodiments, the nitride layers 302 are metal nitride, while the nitride layers 304 are free of the metal element of the nitride layers 302.

In some embodiments, the nitridation process comprises thermal nitridation with a furnace or rapid thermal anneal (RTA) using NH₃, N₂O, N₂, or the like ambient. In other embodiments, the nitridation process may comprise a plasma nitridation and/or a nitrogen implant. For example, a plasma nitridation may be performed in a plasma chamber including NH₃, N₂O, N₂, or the like, and nitrogen plasma may be generated in the plasma chamber. In some embodiments, the thicknesses of the nitride layers 302 and 304 may be in a range from about 0.5 nm to about 4.0 nm.

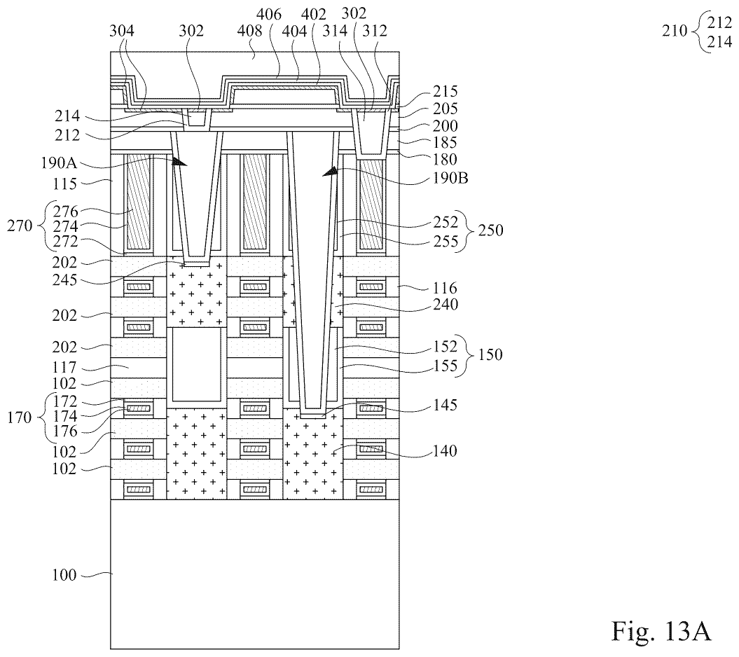

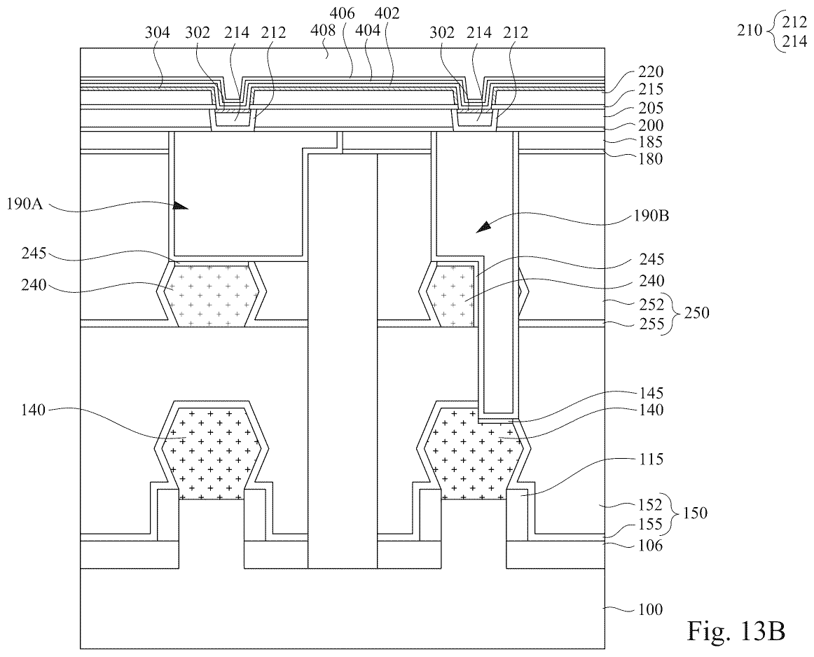

Reference is made to FIGS. 13A and 13B. A barrier layer 402, a conductive layer 404, a conductive layer 406, and a fill metal 408 are sequentially deposited over nitride layers 302 and 304, and filling in the openings O1. In some embodiments, the barrier layer 402 may be in contact with the barrier layer 212 of the via structures 210, the ESL 215, and the nitride layers 302 and 304. The barrier layer 402, the conductive layer 404, the conductive layer 406, and the fill metal 408 may be deposited using techniques such CVD, ALD, or the like.

In some embodiments, the barrier layer 402 may include titanium nitride (TiN), tantalum nitride (TaN), or other suitable materials. The conductive layer 404 may be a metal layer, such as ruthenium (Ru) or other suitable metal. The conductive layer 406 may be a metal layer, such as cobalt (Co) or other suitable metal. The fill metal 408 may be copper (Cu) or other suitable metal. In some embodiments, the material of the barrier layer 402 may include a lower electrical conductivity than the materials of the conductive layer 404, the conductive layer 406, and the fill metal 408.

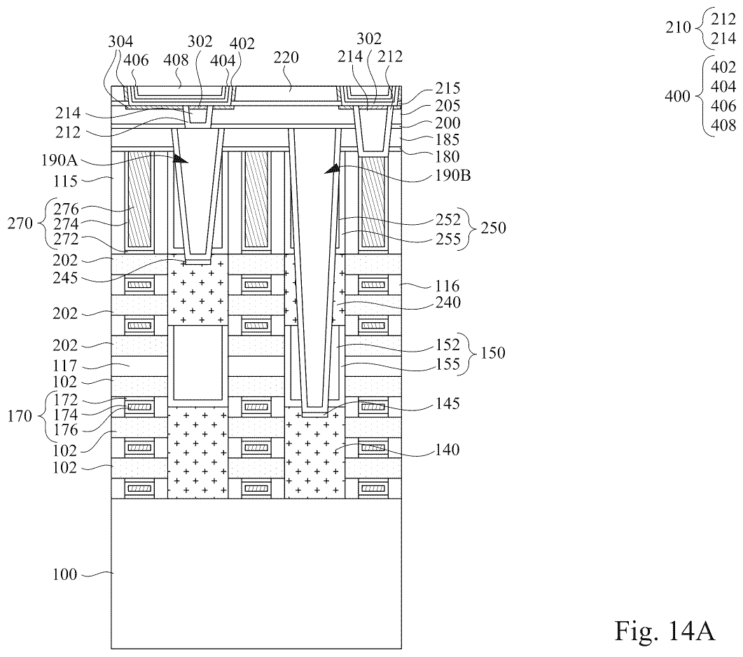

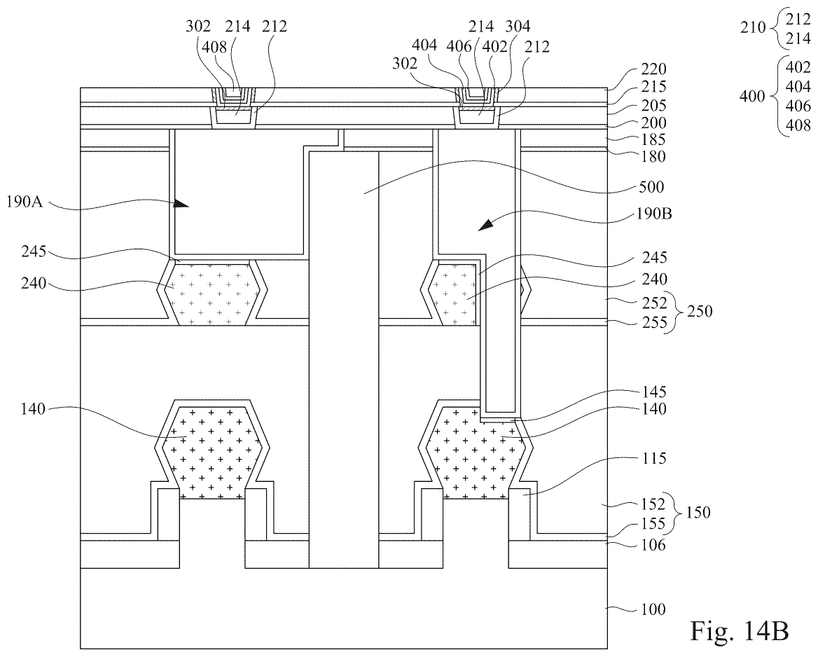

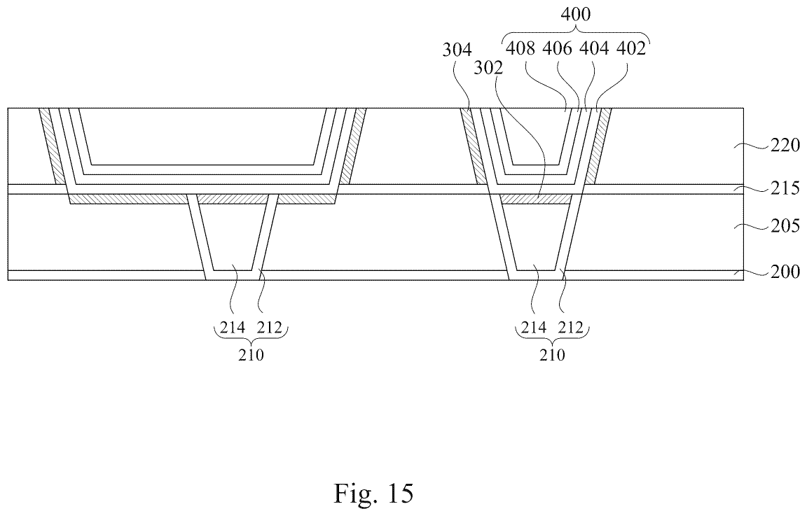

Reference is made to FIGS. 14A, 14B, and 15, in which FIG. 15 is an enlarged view of FIG. 14A. A planarization process, such as CMP, is performed on the structure of FIGS. 13A and 13B, so as to remove excess materials of the nitride layers 304, the barrier layer 402, the conductive layer 404, the conductive layer 406, and the fill metal 408 until the ILD layer 220 is exposed. As a result, conductive lines 400 are formed where each of the conductive lines 400 includes remaining portions of the barrier layer 402, the conductive layer 404, the conductive layer 406, and the fill metal 408. The conductive lines 400 can also be referred to as conductive features or metal lines.

As shown in the enlarged view of FIG. 15, the conductive lines 400 may be electrically connected with the via structures 210, respectively. In some embodiments, the bottom surface of the conductive line 400 is covered by a nitride layer 302. In greater detail, the conductive line 400 is spaced apart from the via 214 of the via structure 210 through the nitride layer 302 and may in contact with the barrier layer 212 of the via structure 210, and is electrically connected with the underlying via structure 210 through the nitride layer 302. On the other hand, opposite sidewalls of the conductive line 400 are covered by a pair of nitride layers 304. In some embodiments, the top ends of the nitride layers 304 may be substantially level with top surface of the conductive line 400. In some embodiments, with respect to the conductive line 400 on the left side of FIG. 15, the nitride layers 304 over the ILD layer 205 may also extend to bottom surface of the conductive line 400, and may separate the bottom surface of the conductive line 400 from top surface of the ILD layer 205. In some embodiments, the structure shown in FIG. 15 can be collectively referred to as an interconnect structure.

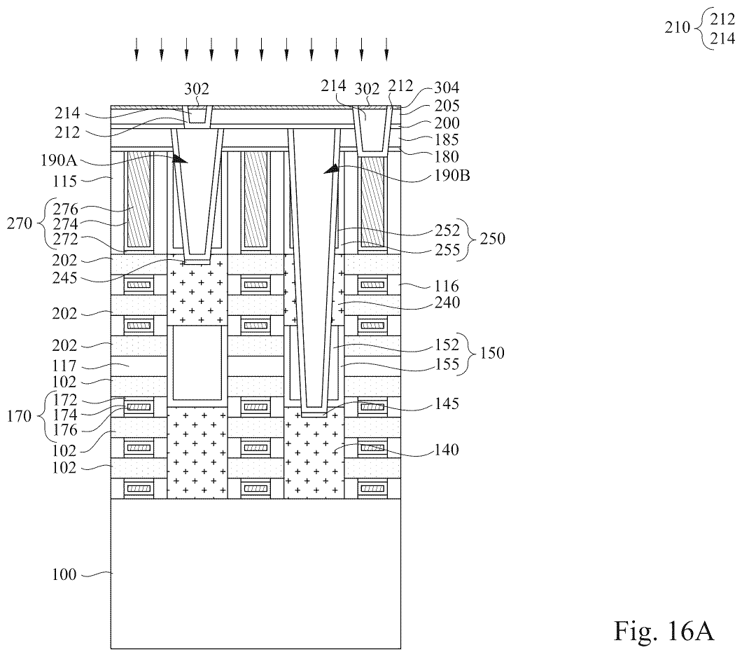

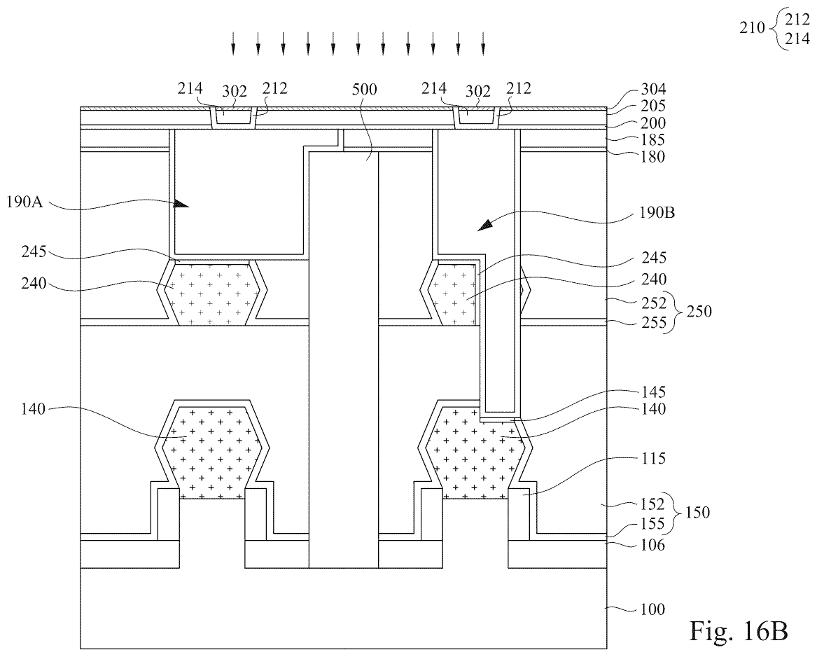

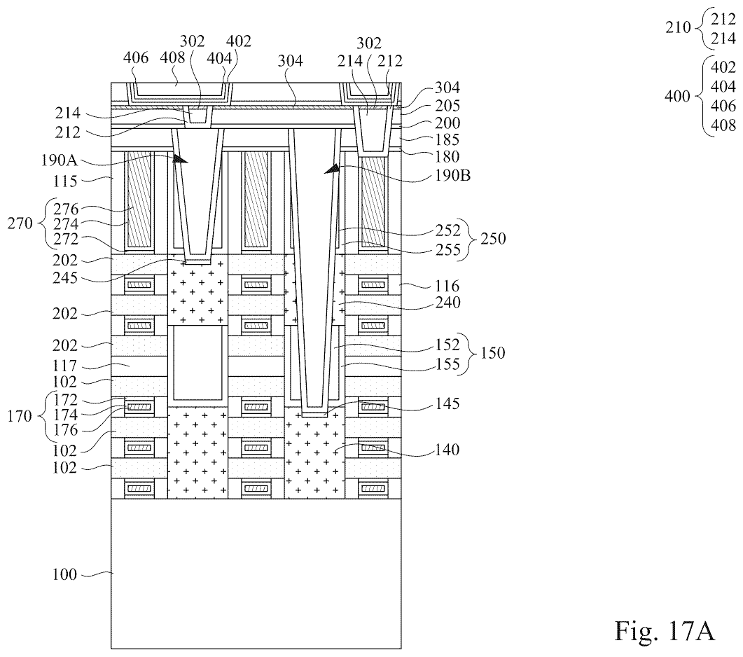

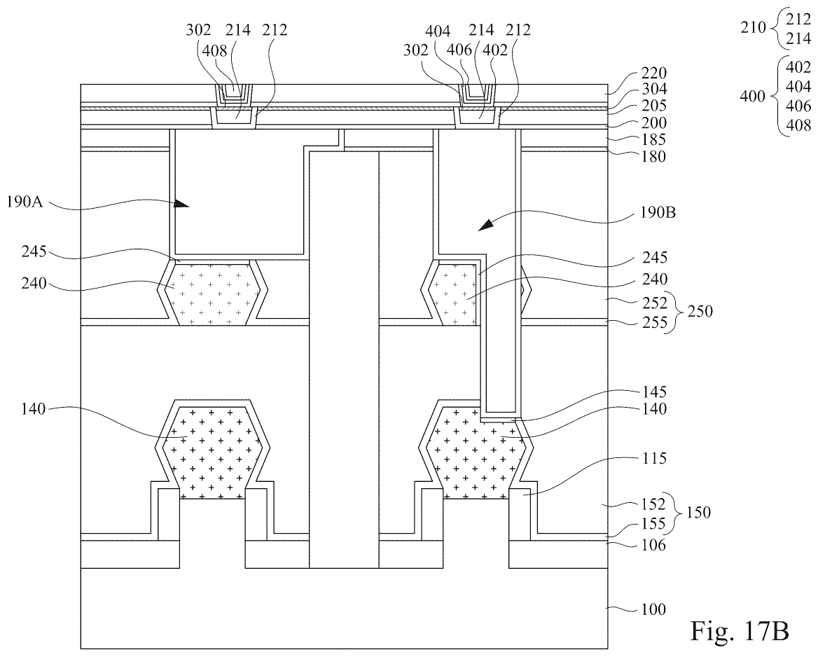

FIGS. 16A to 17B illustrate a method in various stages of forming a semiconductor device in accordance with some embodiments of the present disclosure. It is noted that some elements discussed in FIGS. 16A to 17B are similar to those discussed above, such elements will be labeled the same and relevant details will not be repeated for brevity. The embodiments of FIGS. 16A to 17B are similar to the embodiments of FIGS. 2A to 14B, the difference is that the nitridation process of the embodiments of FIGS. 16A to 17B is performed prior to forming the ESL 215.

Reference is made to FIGS. 16A and 16B. A nitridation process is performed to the structure shown in FIGS. 10A and 10B, so as to form nitride layers lining the exposed surfaces of the structure of FIGS. 10A and 10B. In greater detail, nitride layers 302 are formed on the exposed surfaces of the vias 214 of the via structures 210, and nitride layers 304 are formed along the exposed surfaces of the ILD layer 205.

As mentioned above, because the via 214 of the via structures 210 may be a pure metal layer, such as tungsten (W), molybdenum (Mo), ruthenium (Ru), the nitride layers 302 may be a nitride of the material of the via 214. For example, the nitride layers 302 may be metal nitride, such as tungsten nitride (WN), molybdenum nitride (MoN), ruthenium nitride (RuN). However, because the barrier layer 212 of the via structures 210 may be a metal nitride layer (e.g., TiN, TaN, etc.), the nitridation process may not nitridize the barrier layer 212 of the via structures 210. That is, the nitridation process only nitridize the via 214 of the via structures 210. As a result, the nitride layer 302 over the via 214 may be spaced apart from the adjacent nitride layer 304 on the ILD layer 205 through a corresponding barrier layer 212.

On the other hand, with respect to the nitride layers 304, because the ILD layer 205 may be an oxide layer (e.g., silicon oxide), the nitride layers 304 may be a nitride of the material of the ILD layer 205. That is, the nitridation process only nitridize the ILD layer 205. For example, the nitride layers 304 may be silicon-containing nitride layer, such as oxynitride (SiON). The nitride layers 302 and 304 are made of different nitrides. In some embodiments, the nitride layers 302 are metal nitride, while the nitride layers 304 are free of the metal element of the nitride layers 302. That is, the nitride layers 304 may be metal-free nitride layer.

In some embodiments, the nitridation process comprises thermal nitridation with a furnace or rapid thermal anneal (RTA) using NH₃, N₂O, N₂, or the like ambient. In other embodiments, the nitridation process may comprise a plasma nitridation and/or a nitrogen implant. For example, a plasma nitridation may be performed in a plasma chamber including NH₃, N₂O, N₂, or the like, and nitrogen plasma may be generated in the plasma chamber. In some embodiments, the thicknesses of the nitride layers 302 and 304 may be in a range from about 0.5 nm to about 4.0 nm.

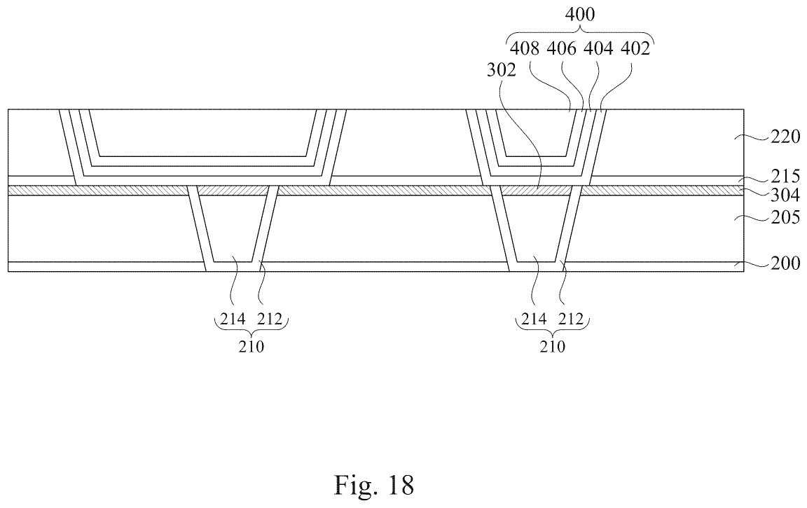

Reference is made to FIGS. 17A, 17B, and 18, in which FIG. 18 is an enlarged view of FIG. 17A. An etch stop layer (ESL) 215 is formed over the ILD layer 205, covering the nitride layers 302 and 304, and an interlayer dielectric (ILD) layer 220 is formed over the ESL 215. Afterwards, conductive lines 400 are formed in the ILD layer 220 and the ESL 215, and are electrically connected with the respective via structures 210. In greater details, the conductive lines 400 are in contact with the nitride layers 302, and may be electrically connected with the respective via structures 210 through the nitride layers 302.

The conductive lines 400 can be formed by, for example, patterning the ILD layer 220 and the ESL 215 to form openings, sequentially depositing a barrier layer 402, a conductive layer 404, a conductive layer 406, and a fill metal 408 filling the openings, and performing a planarization process, such as CMP, to remove excess materials of the barrier layer 402, the conductive layer 404, the conductive layer 406, and the fill metal 408 until the ILD layer 220 is exposed. As a result, conductive lines 400 are formed where each of the conductive lines 400 includes remaining portions of the barrier layer 402, the conductive layer 404, the conductive layer 406, and the fill metal 408. The conductive lines 400 can also be referred to as conductive features or metal lines.

As shown in the enlarged view of FIG. 18, the conductive lines 400 may be electrically connected with the via structures 210, respectively. In some embodiments, the bottom surface of the conductive line 400 is covered by a nitride layer 302. In greater detail, the conductive line 400 is spaced apart from the underlying via structure 210 through the nitride layer 302, and is electrically connected with the underlying via structure 210 through the nitride layer 302. On the other hand, nitride layers 304 are present between the ILD layer 205 and the ESL 215. In some embodiments, with respect to the conductive line 400 on the left side of FIG. 18, the nitride layers 304 may also extend to bottom surface of the conductive line 400, and may separate the bottom surface of the conductive line 400 from top surface of the ILD layer 205. In the embodiments of FIG. 18, opposite sidewalls of the conductive line 400 are in contact with the ESL 215 and the ILD layer 220. In some embodiments, the structure shown in FIG. 18 can be collectively referred to as an interconnect structure.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provides a method by performing a nitridation process to form a nitride layer 302 over the via structure 210, the nitride layer 302 can serve as a diffusion barrier layer to prevent metal elements of the conductive line 400, such as Co or Co, from diffusing downward to the source/drain vias and/or gate vias (e.g., via structure 210). Due the present of nitride layer 302, the thickness of the barrier layer 402 of the conductive line 400 can be reduced, or the barrier layer 402 of the conductive line 400 can even be omitted in the conductive line 400. With such configuration, the resistance of the conductive line 400 can be reduced, and the device performance will be improved.

In some embodiments of the present disclosure, a semiconductor device includes a substrate. A transistor is over the substrate, wherein the transistor comprises a gate structure interfacing at least three surfaces of a channel layer, wherein the gate structure comprises a gate dielectric layer over the channel layer and a gate electrode over the gate dielectric layer. An interconnect structure is over and electrically connected to the plurality of transistor. The interconnect structure includes a via structure, an etch stop layer over the via structure, a dielectric layer over the etch stop layer, wherein a dielectric constant of the gate dielectric layer is greater than a dielectric constant of the dielectric layer, a metal line in the dielectric layer, wherein the metal line includes a barrier layer and a fill metal spaced apart from the dielectric layer by the barrier layer, wherein an electrical conductivity of the barrier layer is less than an electrical conductivity of the fill metal, a first nitride layer vertically between the via structure and the metal line, and second nitride layers on opposite sidewalls of the metal line and in contact with the dielectric layer.

In some embodiments, the first nitride layer and the second nitride layers are made of different nitride materials.

In some embodiments, the first nitride layer is a nitride of a material of the via structure, and the second nitride layers are a nitride of a material of the dielectric layer.

In some embodiments, the first nitride layer is a metal nitride layer, while the second nitride layers is a metal-free nitride layer.

In some embodiments, the semiconductor device further includes a third nitride layer along a bottom surface of the one of metal lines.

In some embodiments, the second nitride layers and the third nitride layer are made of a same nitride material.

In some embodiments, the etch stop layer is in contact with the one of the metal line.

In some embodiments, the one of metal line further comprises a first conductive layer and a second conductive layer between the barrier layer and the fill metal.

In some embodiments of the present disclosure, a semiconductor device includes a substrate. Transistors are over the substrate, wherein at least one of the transistors comprises a source/drain structure. A contact etch stop layer (CESL) is over the source/drain structure. An interlayer dielectric (ILD) layer is over the CESL, wherein a dielectric constant of the CESL is greater than a dielectric constant of the ILD layer. A source/drain contact extends through the ILD layer to electrically couple to the source/drain structure, wherein an electrical conductivity of the source/drain contact is greater than an electrical conductivity of the source/drain structure. A via structure is electrically connected to the at least one of the transistors. A metal line is over and electrically connected to the via structure. A dielectric structure surrounds the metal line. A first nitride layer is vertically between the via structure and the metal line, wherein the first nitride layer is a nitride of a material of the via structure. Second nitride layers are on opposite sidewalls of the metal line and in contact with the dielectric structure, wherein the second nitride layers are a nitride of a material of the dielectric structure.

In some embodiments, the first nitride layer is a metal nitride layer, while the second nitride layers are a silicon-containing nitride layer.

In some embodiments, a portion of the metal line is spaced apart from the dielectric structure through the second nitride layers.

In some embodiments, the semiconductor device further includes a third nitride layer along a bottom surface of the metal line.

In some embodiments, the semiconductor device further includes another dielectric structure surrounding the via structure, wherein the third nitride layer is a nitride of a material of the another dielectric structure.

In some embodiments, the transistors comprises a first transistor and a second transistor vertically above the first transistor.

In some embodiments, the dielectric structure comprises an etch stop layer and an interlayer dielectric layer over the etch stop layer, and the etch stop layer is in contact with the metal line.

In some embodiments of the present disclosure, a method includes forming a plurality of transistors over the substrate, wherein at least one of the transistors comprises a gate structure and a source/drain structure; forming an interlayer dielectric (ILD) layer over the source/drain structure; forming a source/drain contact extending through the ILD layer to electrically couple to the source/drain structure, wherein a conductivity of source/drain contact is greater than a conductivity of the source/drain structure; forming a via structure electrically connected to the source/drain contact; performing a nitridation process to form a first nitride layer on a surface of the via structure, wherein the first nitride layer is a nitride of a material of the via structure; forming a first dielectric layer over the via structure; and forming metal lines in the first dielectric layer, wherein the metal lines are spaced apart from one another through the first dielectric layer, wherein a dielectric constant of a gate dielectric layer of the gate structure is greater than a dielectric constant of the first dielectric layer, and wherein one of the metal lines is electrically connected to the via structure through the first nitride layer.

In some embodiments, the method further includes forming a second dielectric layer over the plurality of transistors, wherein the via structure is formed in the second dielectric layer, wherein the nitridation process is performed prior to forming the first dielectric layer.

In some embodiments, performing the nitridation process further comprises forming a second nitride layer on a top surface of the second dielectric layer, and the second nitride layer is a nitride of a material of the second dielectric layer.

In some embodiments, forming the metal lines in the first dielectric layer comprises forming openings in the first dielectric layer, and wherein the nitridation process is performed through the openings of the first dielectric layer to form the first nitride layer on the surface of the via structure.

In some embodiments, performing the nitridation process further comprises forming a second nitride layer on a sidewall and a top surface of the first dielectric layer, and the second nitride layer is a nitride of a material of the first dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a transistor over the substrate, wherein the transistor comprises a gate structure interfacing at least three surfaces of a channel layer, wherein the gate structure comprises a gate dielectric layer over the channel layer and a gate electrode over the gate dielectric layer;
an interconnect structure over and electrically connected to the transistor and comprising:
a via structure;
an etch stop layer over the via structure
a dielectric layer over the etch stop layer, wherein a dielectric constant of the gate dielectric layer is greater than a dielectric constant of the dielectric layer;
a metal line in the dielectric layer, wherein the metal line includes a barrier layer and a fill metal spaced apart from the dielectric layer by the barrier layer, wherein an electrical conductivity of the barrier layer is less than an electrical conductivity of the fill metal;
a first nitride layer vertically between the via structure and the metal line; and
second nitride layers on opposite sidewalls of the metal line and in contact with the dielectric layer.

2. The semiconductor device of claim 1, wherein the first nitride layer and the second nitride layers are made of different nitride materials.

3. The semiconductor device of claim 2, wherein the first nitride layer is a nitride of a material of the via structure, and the second nitride layers are a nitride of a material of the dielectric layer.

4. The semiconductor device of claim 2, wherein the first nitride layer is a metal nitride layer, while the second nitride layers is a metal-free nitride layer.

5. The semiconductor device of claim 1, further comprising a third nitride layer along a bottom surface of the metal line.

6. The semiconductor device of claim 5, wherein the second nitride layers and the third nitride layer are made of a same nitride material.

7. The semiconductor device of claim 1, wherein the etch stop layer is in contact with the one of the metal line.

8. The semiconductor device of claim 1, wherein the metal line further comprises a first conductive layer and a second conductive layer between the barrier layer and the fill metal.

9. A semiconductor device, comprising:
a substrate;
transistors over the substrate, wherein at least one of the transistors comprises a source/drain structure;
a contact etch stop layer (CESL) over the source/drain structure;
an interlayer dielectric (ILD) layer over the CESL, wherein a dielectric constant of the CESL is greater than a dielectric constant of the ILD layer;
a source/drain contact extending through the ILD layer to electrically couple to the source/drain structure, wherein an electrical conductivity of the source/drain contact is greater than an electrical conductivity of the source/drain structure;
a via structure electrically connected to the at least one of the transistors;
a metal line over and electrically connected to the via structure;
a dielectric structure surrounding the metal line;
a first nitride layer vertically between the via structure and the metal line, wherein the first nitride layer is a nitride of a material of the via structure; and
second nitride layers on opposite sidewalls of the metal line and in contact with the dielectric structure, wherein the second nitride layers are a nitride of a material of the dielectric structure.

10. The semiconductor device of claim 9, wherein the first nitride layer is a metal nitride layer, while the second nitride layers are a silicon-containing nitride layer.

11. The semiconductor device of claim 9, wherein a portion of the metal line is spaced apart from the dielectric structure through the second nitride layers.

12. The semiconductor device of claim 9, further comprising a third nitride layer along a bottom surface of the metal line.

13. The semiconductor device of claim 12, further comprising another dielectric structure surrounding the via structure, wherein the third nitride layer is a nitride of a material of the another dielectric structure.

14. The semiconductor device of claim 9, wherein the transistors comprises a first transistor and a second transistor vertically above the first transistor.

15. The semiconductor device of claim 9, wherein the dielectric structure comprises an etch stop layer and an interlayer dielectric layer over the etch stop layer, and the etch stop layer is in contact with the metal line.

16. A method, comprising:
forming a plurality of transistors over a substrate, wherein at least one of the transistors comprises a gate structure and a source/drain structure;
forming an interlayer dielectric (ILD) layer over the source/drain structure;
forming a source/drain contact extending through the ILD layer to electrically couple to the source/drain structure, wherein a conductivity of source/drain contact is greater than a conductivity of the source/drain structure;
forming a via structure electrically connected to the source/drain contact;
performing a nitridation process to form a first nitride layer on a surface of the via structure, wherein the first nitride layer is a nitride of a material of the via structure;
forming a first dielectric layer over the via structure; and
forming metal lines in the first dielectric layer, wherein the metal lines are spaced apart from one another through the first dielectric layer, wherein a dielectric constant of a gate dielectric layer of the gate structure is greater than a dielectric constant of the first dielectric layer, and wherein one of the metal lines is electrically connected to the via structure through the first nitride layer.

17. The method of claim 16, further comprising forming a second dielectric layer over the plurality of transistors, wherein the via structure is formed in the second dielectric layer, wherein the nitridation process is performed prior to forming the first dielectric layer.

18. The method of claim 17, wherein performing the nitridation process further comprises forming a second nitride layer on a top surface of the second dielectric layer, and the second nitride layer is a nitride of a material of the second dielectric layer.

19. The method of claim 16, wherein forming the metal lines in the first dielectric layer comprises forming openings in the first dielectric layer, and wherein the nitridation process is performed through the openings of the first dielectric layer to form the first nitride layer on the surface of the via structure.

20. The method of claim 19, wherein performing the nitridation process further comprises forming a second nitride layer on a sidewall and a top surface of the first dielectric layer, and the second nitride layer is a nitride of a material of the first dielectric layer.
